(19) United States
(12) Patent Application Publication
(10) Pub. No.: US 2012/0132258 A1
(43) Pub. Date: May 31, 2012

(54) SOLAR COLLECTOR

(75) Inventors: Emanuele Albanese, Collegno (Torino) (IT); Andrea Benini, Acqui Terme (Alessandria) (IT)

(73) Assignee: Emanuele ALBANESE, Collegno (Torino) (IT)

(21) Appl. No.: 13/321,384

(22) PCT Filed: May 19, 2010
(86) PCT No.: PCT/IB2010/052221

§ 371 Date: Feb. 17, 2012

(30) Foreign Application Priority Data
May 19, 2009 (IT) TO2009A000382

(51) Int. Cl. H01L 31/058; B21D 53/02; H01L 31/18; F24J 2/12; F24J 2/04

(52) U.S. Cl. 136/248; 126/690; 126/634; 29/890.033

(57) ABSTRACT

A solar collector includes a concentrator having a circular paraboloid-shaped reflective surface, and receiver facing the concentrator. The concentrator has a plurality of circular paraboloid-portion-shaped mirrors, made of hot formed glass, and has respective circle-arc-shaped inner edges, which, in the mutually assembled condition, delimit a discharge hole at the center of the concentrator.

### FIELD OF THE INVENTION

The present invention refers to a solar collector of the type comprising a support structure and a solar concentrator borne by the support structure, wherein the solar concentrator comprises a circular parabolid-shaped reflective surface, and a receiver facing the concentrator.

### PRIOR ART

Solar collectors of this type, provided with a circular palaboloid-shaped concentrator, are typically used for heating a thermal carrier fluid which passes through the receiver. These solar collectors have relatively high operating performance which allows obtaining high temperatures (beyond 600° C.) of the thermal carrier fluid, even with relatively limited extensions of the concentrator.

For such reason, solar collectors of the type in question are becoming more common even for applications in the private and/or household environment, where the available spaces are necessarily limited.

However, currently known solar collectors poorly adapt to large scale use. As a matter of fact, a first known type of solar collector provides for a concentrator whose reflective surface is formed by arranging a plurality of flat mirrors on a concave support structure. The step of assembling this type of reflective surface is extremely long and complex, in that it requires that each mirror that is intended to form it be suitably directed towards the receiver. Furthermore, such type of reflective surface considerably jeopardises the overall efficiency of the concentrator, lowering performance thereof, in that the flat mirrors create—in their entirety—a mere approximation of an ideal circular paraboloid surface, this approximation additionally being positioned at a distance depending on the dimensions of the concentrator, i.e. the smaller the concentrator the farther the approximation. A solar collector of this type is for example described in the United States patent U.S. Pat. No. 6,336,452B1.

A second known type of solar collector with circular parabolid-shaped reflective surface, instead provides for a flexible reflective membrane which is stretched in such a manner to acquire the circular paraboloid shape. A structure of this type is particularly delicate, expensive, and, above all, it requires the intervention of skilled specialized technicians for proper assembly thereof. A solar collector of this type is for example described in the U.S. Pat. No. 4,875,467.

Document DE-29606714 describes a solar collector corresponding to the preamble of claim 1, wherein the concentrator comprises a plurality of circular paraboloid-portion-shaped mirrors, which are prearranged to be mutually arranged, in the assembled condition of the concentrator, into a single circular series, which in its entirety defines said reflective surface.

### SUMMARY OF THE INVENTION

In the technical field in question there arises the need for a solar collector having a simple structure, robust, easy to install and being relatively inexpensive, and also suitable to ensure higher performance.

The present invention has the object of a solar collector capable of meeting the abovementioned requirements, due to the characteristics outlined primarily in claim 1 and secondarily in the subordinate claims.

The discharge hole provided for according to the invention at the centre of the concentrator has the double function of improving the aerodynamics of the collector, allowing the wind to pass through the concentrator, thus avoiding formation of vertical stagnation at the concave part of the concentrator, which would lead to excessive vibrational stresses on the entire collector, and create a system for natural ventilation of air having the function of cooling the reflective surface of the concentrator.

Provided for in a preferred embodiment of the solar collector according to the present invention is a system for washing the concentrator comprising means for spraying a cleaning liquid against the reflective surface of the latter. In such embodiment, the discharge hole has the further function of discharging such cleaning liquid outside the concentrator.

The present invention also has the object of a method for making and assembling a solar collector of the abovementioned type, which provides for the hot forming of a plurality of circular paraboloid-portion-shaped glass mirrors and a step for assembling the reflective surface which provides for the arrangement of said mirrors, on said support structure, only into one circular series.

Preferred characteristics of the invention are included in the description that follows and in the attached claims, which shall be considered an integral part of the description.

### BRIEF DESCRIPTION OF THE DRAWINGS

Further characteristics and advantages of the invention shall be made clear by the attached drawings, strictly provided for exemplifying and non-limiting purposes, wherein:

FIG. 1 represents a perspective view of a solar collector according to the present invention;

FIG. 2 represents a sectional view according to a plane of FIG. 1, passing through the axis 10′ and orthogonal to the concentrator 2;

FIG. 3 represents a plan view of the detail of the collector of FIG. 1,

FIG. 4 represents the perspective view of a solar collector according to the present invention provided with a cleaning system,

FIG. 5 is a schematic and simplified view of a variant of the solar collector,

FIGS. 6 and 7 are two perspective schematic views, respectively dorsal and front, of a further variant of the solar collector, for generating electrical energy,

FIGS. 8 and 9 are two schematic perspective views, respectively dorsal and front, of a further variant of the solar collector according to the invention, and

FIG. 10 is a perspective view—in larger scale—of a detail of the concentrator according to FIGS. 6, 7 and 8, 9.

### DETAILED DESCRIPTION OF THE EMBODIMENTS OF THE INVENTION

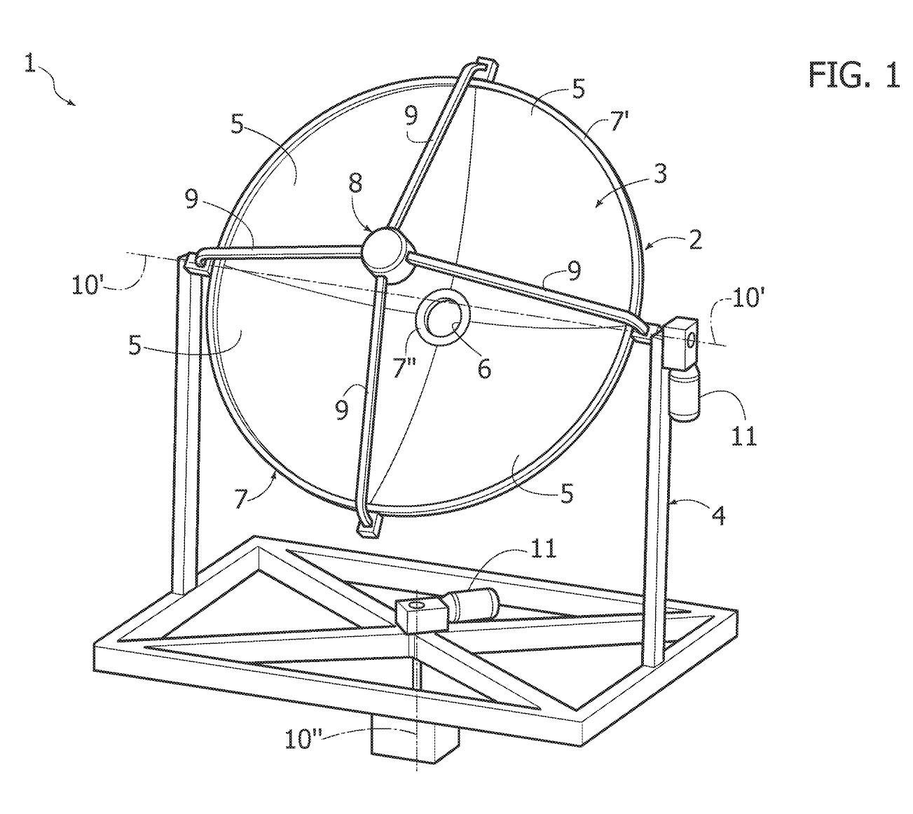

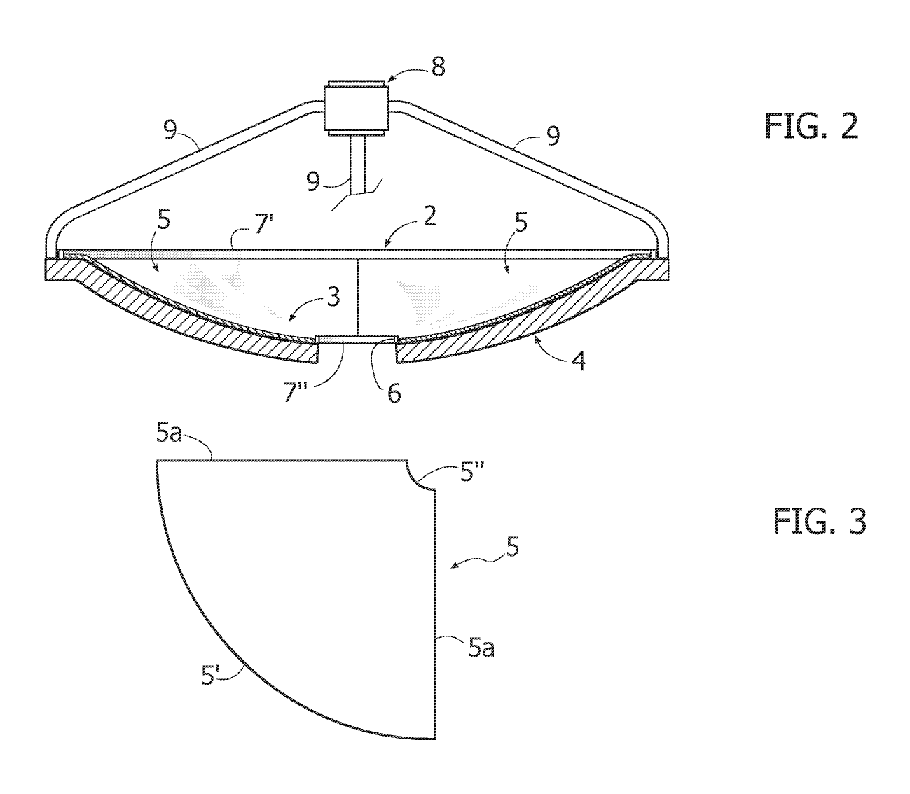

FIG. 1 illustrates a solar collector 1 comprising a concentrator 2 having a circular paraboloid-shaped reflective surface 3. In particular, the concentrator 2 comprises a plurality of circular paraboloid-portion-shaped mirrors 5, which are mutually arranged into a circular series, which—in its entirety—defines the reflective surface 3. The mirrors 5 are made of hot formed glass and specifically they have a double layer glass structure (twin glass), with the interposition of a reflective layer. The double layer glass structure has two glass layers, or a glass layer and a fibre glass layer. The method for making the mirrors 5 initially provides for forming the circular paraboloid-portion-shaped glasses, through forming moulds which are passed through a furnace, having a temperature suitable to render the glass malleable without altering properties thereof. A tempering operation is performed subsequently and then a mirroring process is started. Should the mirrors 5 have a fibre glass layer, as described previously, a further process consisting in applying the same glass fibre through spraying is provided for.

More in detail, the method for forming the portions of the mirrors 5 provides for the use of gravitational forming moulds through some passages in a furnace having temperatures suitable to render the glass malleable without altering mechanical properties thereof and allow obtaining the curving of the portions.

Upon obtaining the desired shape there follows the tempering treatment, which may be a traditional tempering obtained through heat excursion, or through chemical treatment.

Once tempered, each glass portion is moved on to the silver-coating process performed by spraying on the side opposite with respect to the curving.

Then, another glass portion is applied—by means of a thermal process—at rear part of the first silver-coated portion to protect the silver coating in question.

Each portion is thus made up of a lamination formed by two layers of glass with a silver-coated layer (twin glass structure) interposed therebetween.

Given the type of glass lamination (which occurs at around 145° C.), when the temperature reaches the threshold of 100-105° C. there starts a detachment process the glass elements.

This does not represent a significant problem for most of the applications, save for those located in subtropical or equatorial areas.

Another method for making the portions of the solar collector was considered for the applications in these areas in order to overcome this problem.

Portions are made using precious metals (Au, Pt). The curving process remains unaltered with respect to the previous one, even in cases where the glass used has a greater thickness (about 8 mm against about 4 mm of the single layer of the twin glass structure).

The difference lies in the fact that the application of the mirroring process provides for the use of precious metals for the silver-coating and this allows the portion to operate at much higher operating surface temperatures (about 250° C.)

However, a substantial difference lies in the fact that mirroring using precious metals does not allow tempering the support glass, given that the glass would be tempered due to the high temperatures for the application of the layer of precious metals.

Alongside the abovementioned increase of the thickness of the glass itself, a suitable coating made of polymer material shall be applied at the rear part of the portion in order to overcome the lack of the second glass layer and obtain an ideal safety level of the structure.

Provided for to reduce or almost entirely eliminate the environmental impact is the application of a layer of paint—at the rear of the portions and on the entire structure—having a tonality matching the surrounding site.

The portions 5 (circular paraboloid-shaped) may be assembled misaligned with respect to the design position, in order to emulate the shape of a mirror-distributed focus.

The off-focus assembly of the portions has the aim of virtually increasing the dimensions of the focal zone thus obtaining a greater tolerance for the solar rays not parallel to the axis of the collector and reducing the sensitivity of the system to possible errors by the sun tracker system, to be addressed hereinafter.

Also provided for may be the application of the so-called non-imaging technology to the making of a particular form of paraboloid, made up of the rotation around a suitable symmetry axis of a parabolic arc bearing the focus at a decentred position with respect to said axis. This generates a curvilinear surface capable of concentrating the solar energy along a circular crown-shaped distributed focus and/or along a suitably shaped reflective mirror adapted to convey the light through the discharge hole, also to be addressed hereinafter. This allows guaranteeing an extension of the receptivity of the parabola for solar rays not perfectly parallel to the symmetry axis, and the sensitivity of the system to possible errors by the tracker device is reduced.

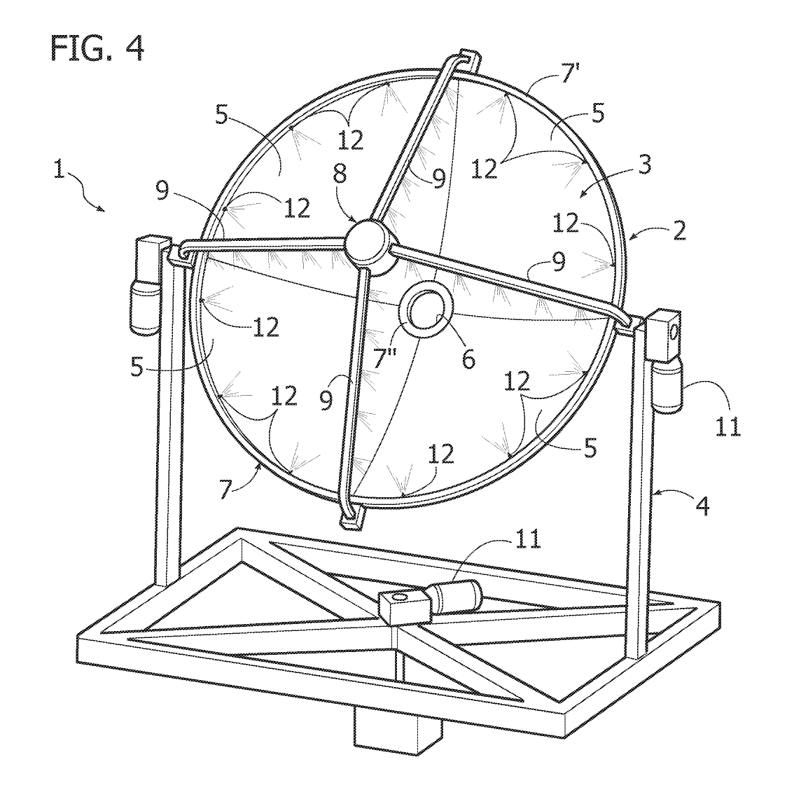

Illustrated in FIG. 3 is a plan view of a mirror 5. As observable from such figure, each mirror 5 comprises an outer edge 5′ and an inner edge 5″, both having a circular-arc profile, and side edges 5a having a parabolic-section profile.

With the aim of obtaining—in their entirety—the circular parabolid-shaped reflective surface, the mirrors 5 are mutually arranged into a circular series on a support structure 4 of the solar collector 1. The structure 4 may comprise a frame 7 into which the mirrors 5 are fixed, in a configuration wherein each mirror 5 is adjacent to other two mirrors, at the respective parabolic section side edges 5a thereof.

The frame 7 comprises an outer ring 7′ and an inner ring 7″, which are engaged respectively by the outer edge 5′ and by the inner edge 5″ of the mirrors 5. In a preferred embodiment, instead of the outer ring 7″, the frame 7 has clip elements which end up solely engaging the adjacent portions of the outer edges 5″ of each pair of mirrors adjacent with respect to each other.

From the information above, it is clear that the concentrator 2 described above is easy to assemble, in an intuitive manner, arranging on the frame 7 the circular series of the mirrors 5, which—in their entirety—ends up forming the reflective surface 3 in the exact geometry of a circular paraboloid. The implementation step of may be supported by the presence—at the rear part of the frame 7—by raising rings that allow quickening such operation. The implementation of the circular paraboloid of the mirrors 5 by portion is also advantageous due to the fact that possible thermal dilatations of the mirrors are distributed along the preferential radial and circumferential directions, hence the geometry of each single mirror and the overall one of the reflective surface are not altered due to the dilatations. Thus, such thermal dilatations do not influence the efficiency of the collector and are totally absorbed by the clearances by means of which the mirrors 5 are mounted on the frame 7.

The frame 7 is in turn mounted on a solar tracker structure 10 through which the concentrator 2 can be directed around a horizontal axis 10′ thereof and around a second vertical axis 10″. Electric motors 11 drive the rotations of the concentrator 2 around the abovementioned first and second axis. The solar tracker device may however be obtained in any known manner, hence it shall not be described in detail herein with the aim of rendering the description easier to understand.

Furthermore, the solar collector comprises a receiver 8 arranged at a position corresponding to the geometrical focus of the reflective surface 3, or even at a staggered position with respect to the focus, which serves to absorb the thermal energy generated by the incident solar rays thereon and transfer such thermal energy to a thermal carrier fluid which is conveyed to/from the receiver through the pipes 9, in fluid communication with the receiver itself. Such pipes 9 also serve to support the receiver in the geometrical focus position thereof, and they are in turn borne by the frame 7. In the specified example of FIG. 1, the solar collector comprises four pipes arranged radially with respect to the receiver, at 90 degrees with respect to each other, whereof a pair of pipes opposite with respect to the receiver, are suitable to supply the thermal carrier fluid to the receiver, while the other pair of opposite pipes, conveys the thermal carrier fluid, flowing out from the receiver, to a unit for exploiting the thermal energy (not shown in the figures). The method for connecting the pipes 9 to an external thermal system, which also includes the abovementioned exploitation unit, is not described herein, in that such connection may be obtained in any manner known to the man skilled in the art. Furthermore, the receiver 8 may be obtained according to any other structure suitable to transfer the thermal energy provided by the incident solar rays thereon to the thermal carrier fluid. The pipes 9 may be made of an aluminium alloy or any other material suitable for transferring the fluid at a high temperature.

The inner ring of the frame 7 defines a discharge hole 6 which, due to the fact that it provides a passage by means of which the air passes through concentrator, serves to release the overpressure that is created in case of incident wind on the concentrator, and furthermore, eliminate the formation of vortices, at the concave part of the concentrator, which subject the entire structure of the solar collector to vibrational stresses.

The discharge hole 6 also serves to trigger a natural circulation of air that facilitates the cooling of the reflective surface of the concentrator. Such discharge hole has a diameter that is proportional to the diameter of the concentrator, and which—in a preferred embodiment—corresponds to a tenth of the diameter of the concentrator.

Represented in FIG. 4 is a further embodiment of the solar collector according to the present invention, provided in which is a system for washing the concentrator. Such system comprises nozzles 12 mounted at the outer ring of the frame 7 and on the pipes 9, which are adapted to spray a suitable cleaning fluid, such as demineralised water, against the reflective surface 3 of the concentrator. In such embodiment the discharge hole 2 serves the further function of releasing the cleaning liquid from the concentrator.

For applications in particularly harsh environmental conditions (for example desert sand) also provided for is the installation of a self-propelled automatic system for cleaning the glass surface, not represented in the drawings.

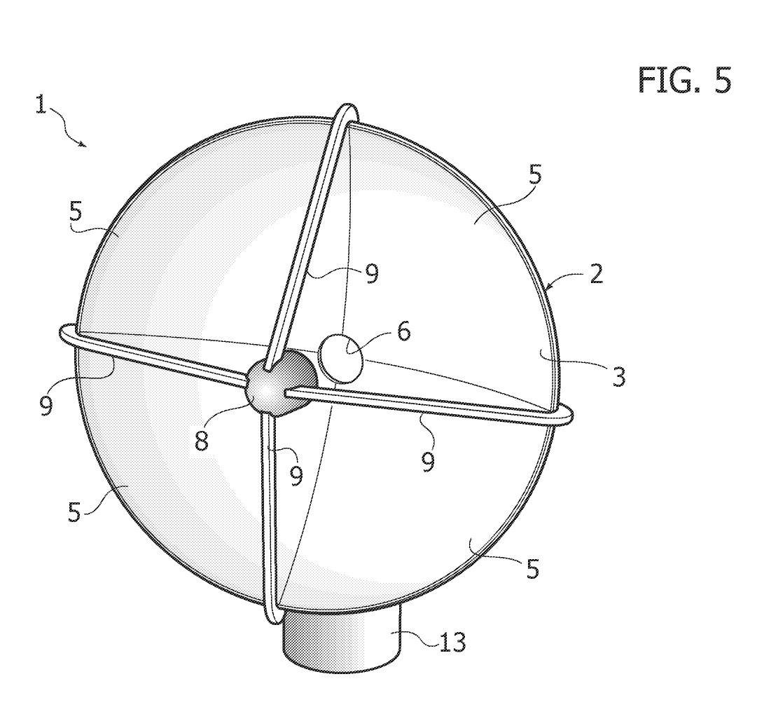

In the case of the variant illustrated in FIG. 5 the support structure of the solar collector 1 is made up of a pole 13 bearing the tracker device.

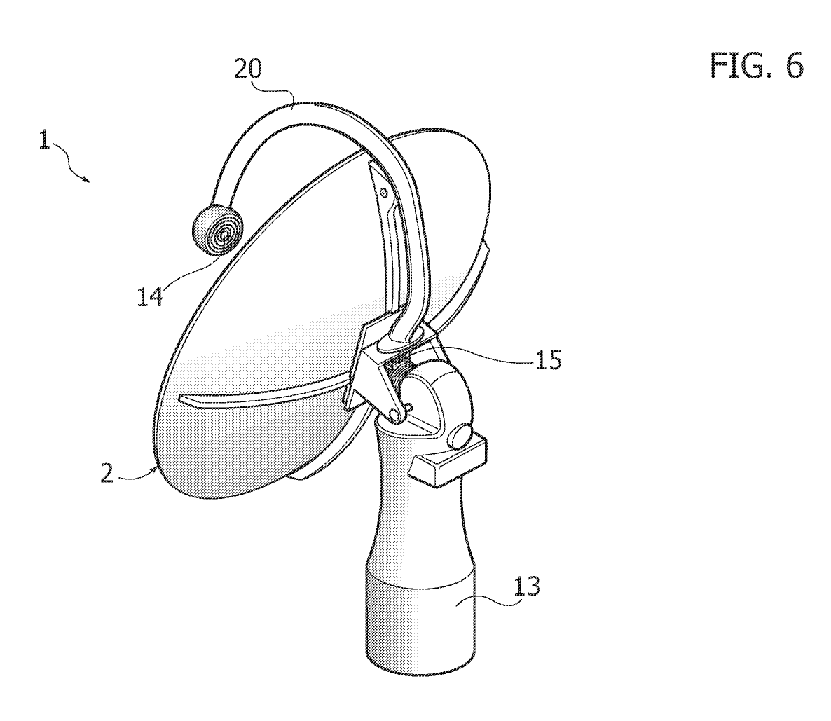

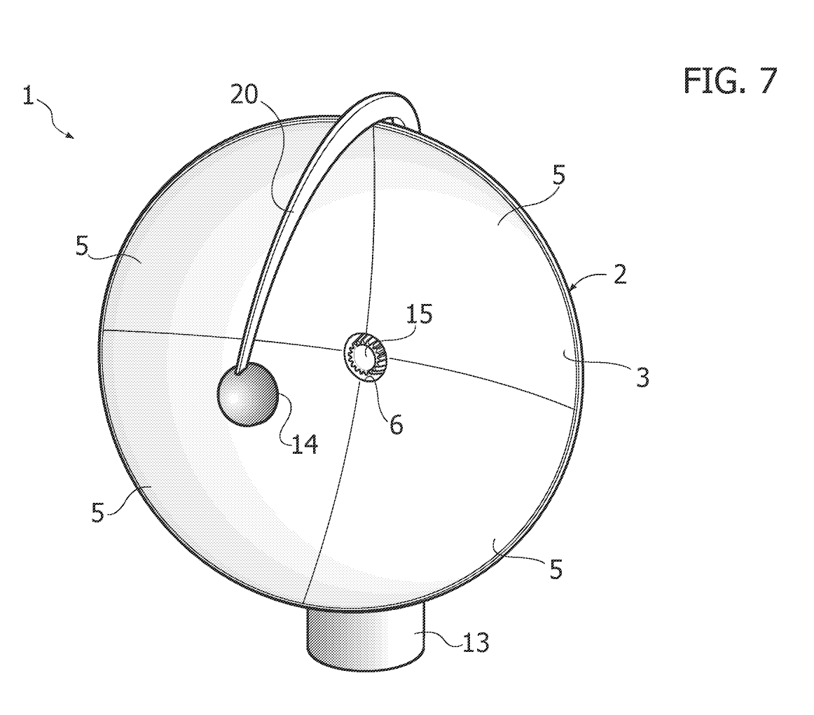

FIGS. 6 and 7 illustrate the application of the solar collector 1 according to the invention to a concentration photovoltaic system for the generation of electrical energy or also for the cogeneration of heat in thermal/refrigerant systems.

In this case, the parabolic concentrator 2 concentrates the solar rays at a point positioned along the symmetry axis thereof, for example immediately behind the discharge hole 6, through reflection by means of a concave mirror 14 borne for example by a curved arm 20, fixed at the top part of the pole 13, and positioned at or in proximity to the geometrical focus of the concentrator 2.

Arranged at the area of the point where the concave mirror 14 concentrates the solar rays is a combination of concentration photovoltaic cells, generally indicated with 15, capable of absorbing a radiation equivalent to multiple values of the solar one.

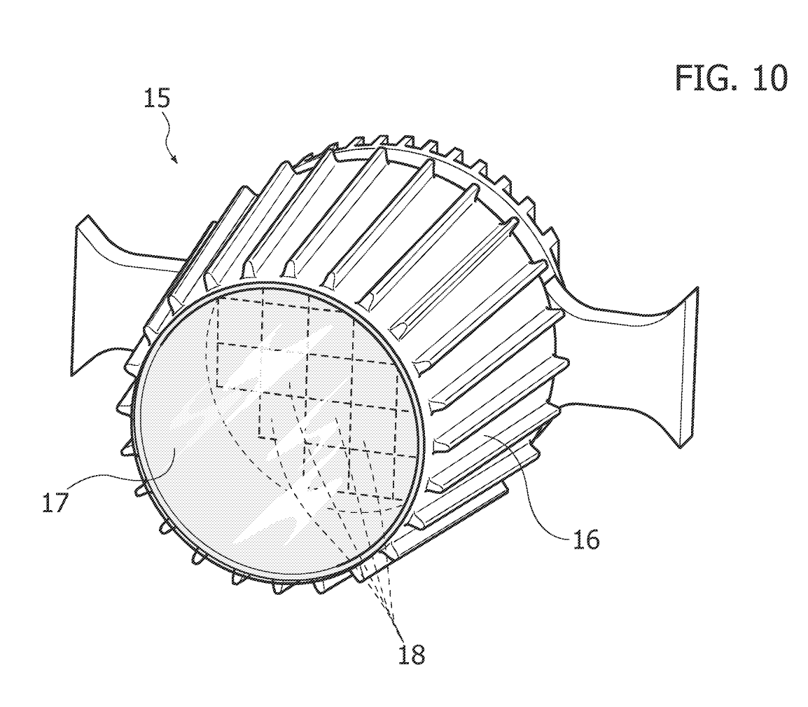

A system for focusing the solar rays is installed to protect the photovoltaic cells in such a manner to guarantee suitable cooling and mount the cells at a shadow zone: as illustrated in detail in FIG. 10 it is made up of a diverging tubular body 16 made of glass or any other material, having outer fins and having the inner wall mirror-polished, closed at the head by a lens 17 made of quartz, glass or other material capable of insulating the interior environment allowing the passage of light with minimum absorption and bearing at the end a plate made of copper, aluminium or other thermal conductor material (not illustrated) on which the concentration cells 18 are installed.

Such plate may bear pipes therein for the passage of a cooling fluid and/or finned, same case applying to the tubular body 16, maintained wherein is a pressure lower than the atmospheric pressure to reduce thermal transfer by convection and minimise the absorption of energy by an interior gas.

The cooling of the cells 18 may occur by reutilising the exhaust heat, for example with production of refrigerant power by means of an absorption method, or provided for may be a suitable heat discharge system.

The solar rays are focused through multiple reflections against the interior surface of the tubular body 16 and this allows transferring most energy possible to the cells 18. Non-imaging optical systems may be used.

The dimensions of the tubular body 16 may be equivalent or smaller than the dimension of the discharge hole 6 and concentric or off-axis assembly thereof allows discharging the cleaning liquid and/or the passage of air into the interface left between the tubular body 16 and discharge hole 6.

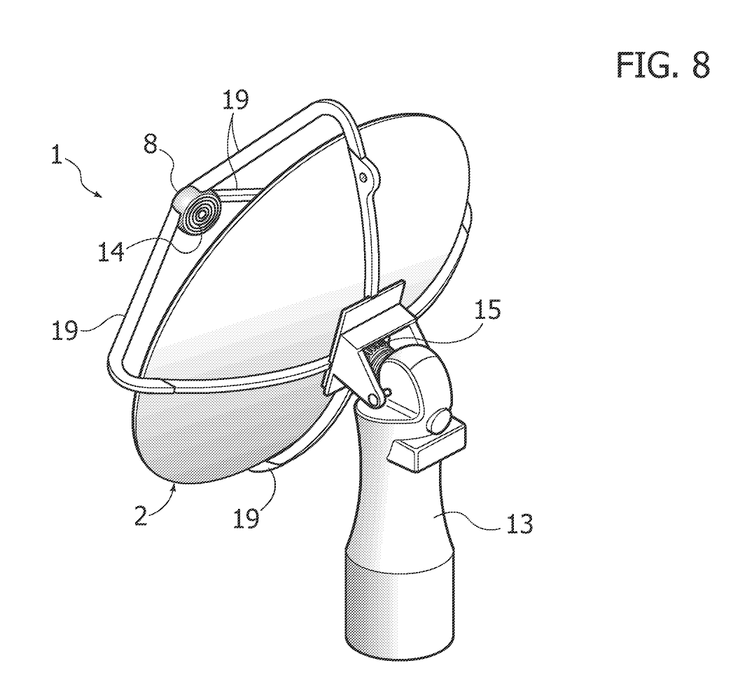

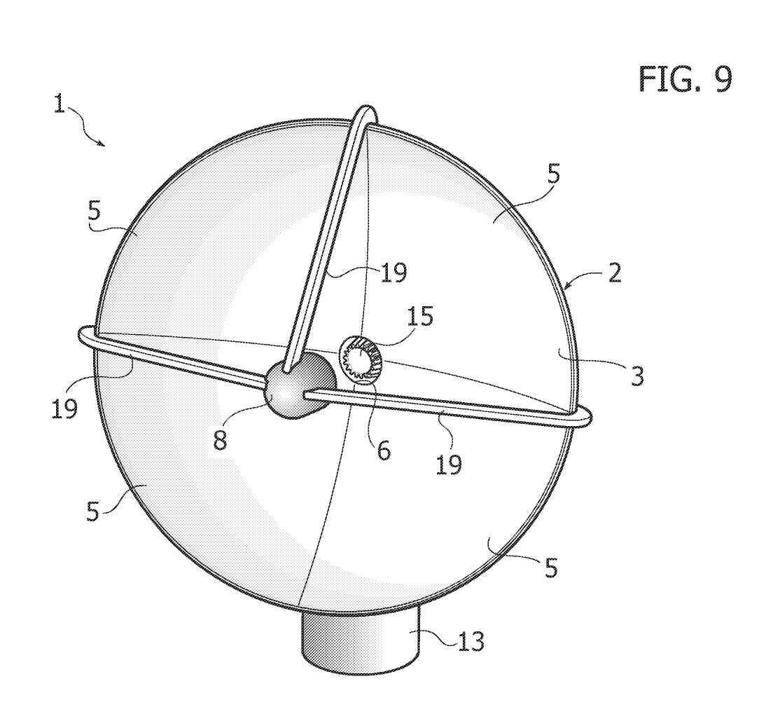

FIGS. 8 and 9 illustrate the application of the solar collector 1 according to the invention to a combined thermal system with thermal carrier fluid and electrical system with photovoltaic cells. In such case, the mirror 14 is combined with the receiver 8 borne by the arms 19 that may also serve as pipes for the circulation of the thermal carrier fluid.

It should be observed that the configuration of the solar collector according to the invention allows, through simple and quick operations, conversion thereof from the thermal energy production version to the electrical energy production version, and vice versa. As a matter of fact, the modularity and interchangeability of the components thereof, particularly of the receiver 8 and of the mirror 14 together with the photovoltaic cells 15 associated thereto, allows selectively using the same mirror concentrator 2 completing it with the different types of solar energy exploitation, hence allowing alternative use thereof for producing thermal energy or electrical energy, simply by changing the receiving system.

Obviously, the construction details may widely vary with respect to what has been described and illustrated without departing from the scope of protection of the present invention, as defined by the attached claims.

Thus, the pole for supporting the solar collector may also be replaced by simple I-shaped beam elements joined by a suitable support and driven into the ground.

1. Solar collector comprising:
a support structure;
a solar concentrator borne by said support structure, wherein said concentrator comprises a circular paraboloid-shaped reflective surface,
a receiver facing the concentrator,
wherein said concentrator comprises a plurality of circular paraboloid-portion-shaped mirrors, which are prearranged to be mutually arranged, in the assembled condition of the concentrator, into a single circular series which in its entirety defines said reflective surface, and
said mirrors made of hot formed glass and having respective circular arc-shaped inner edges, which, in such assembled condition, delimit a discharge hole at the center of said concentrator.

2. Solar collector according to claim 1, further comprising pipes in fluid communication with said receiver, which are further prearranged to support said receiver substantially at the geometrical focus of said concentrator.

3. Solar collector according to claim 1, further comprising a concave mirror substantially supported at the geometrical focus of said concentrator and directed towards a combination of photovoltaic cells positioned in proximity to said discharge hole.

4. Solar collector according to claim 3, wherein said combination of photovoltaic cells is accommodated in an internally reflecting protection tubular body.

5. Solar collector according to claim 1, further comprising a cleaning device adapted to spray a cleaning liquid against said reflective surface.

6. Solar collector according to claim 5, wherein said cleaning device comprises nozzles arranged on said pipes and/or around said reflective surface.

7. Solar collector according to claim 1, wherein said mirrors have a double layer glass structure, with the interposition of a reflective layer.

8. Solar collector according to claim 7, wherein said double layer glass structure has two glass layers or a glass layer and a fibre glass layer.

9. Solar collector according to claim 1, wherein the collector is selectively useable for producing thermal or electrical energy by using respective interchangeable receivers.

10. Method for making and assembling a solar collector of the type according to claim 1, comprising hot forming of a plurality of mirrors made of circular paraboloid-portion-shaped glass and assembling the reflective surface to provide for the arrangement of said mirrors, on said support structure, in a single circular series.

11. Solar collector according to claim 2, further comprising a concave mirror substantially supported at the geometrical focus of said concentrator and directed towards a combination of photovoltaic cells positioned in proximity to said discharge hole.
